(19) United States
(12) Patent Application Publication
(10) Pub. No.: US 2025/0385487 A1
(43) Pub. Date: Dec. 18, 2025

(54) STRUCTURES FOR IN-SITU REFLECTANCE MEASUREMENT DURING HOMO-EPITAXY

(71) Applicant: Yale University, New Haven, CT (US)

(72) Inventors: Jin-ho Kang, New Haven, CT (US); Jung Han, New Haven, CT (US)

(21) Appl. No.: 18/880,123

(22) PCT Filed: Jun. 30, 2023
(86) PCT No.: PCT/US23/69466

§ 371 Date: Dec. 30, 2024

Related U.S. Application Data
(60) Provisional application No. 63/357,931, filed on Jul. 1, 2022.

(51) Int. Cl. H01S 5/183; G01B 11/06

(52) U.S. Cl. CPC H01S 5/18361; G01B 11/0625; G01B 11/0683; G01B 2210/56

(57) ABSTRACT

Provided herein are a semiconductor layered structure and a method of producing the same. The semiconductor layered structure includes a substrate layer including a semiconductor material, an index layer on the substrate layer, and at least one reflective layer on the index layer, wherein the substrate layer and the reflective layer include substantially the same refractive indices. The method includes growing, via an epitaxial process, the reflective layer onto the index layer; measuring, via a reflectometer, a thickness of the reflective layer; and terminating the epitaxial process at a desired thickness of the reflective layer.

### CROSS-REFERENCE TO RELATED APPLICATIONS

The present application claims priority under 35 U.S.C. § 119(e) to U.S. Provisional Patent Application No. 63/357,931, filed Jul. 1, 2022, which application is incorporated herein by reference in its entirety.

### BACKGROUND OF THE INVENTION

Nanoporous (NP) distributed Bragg reflectors (DBRs) can be formed after epitaxial growth through a conductivity-selective electrochemical etching. By changing only the conductivity of the same semiconductor material, the heavily-doped (more conductive) layers can be selectively porosified while leaving the lightly-doped or undoped layers intact. The great advantage of this method is that the complexity in conventional heteroepitaxy, i.e., growing compositionally different semiconductor layers, can be replaced by homoepitaxy (growing the same material) of layers with the only difference being the doping level in each layer. The layers used for NP DBRs are typically grown on substrates of the same materials to minimize the generation of any microstructural defects and to ensure the highest structure quality. When all of these factors are combined, there arises a unique challenge in growth, namely the accurate, reproducible, and real-time control of the thicknesses of layers in the construction of vertical cavity surface emitting lasers (VCSELs).

Thickness control is an important task in VCSEL manufacturing. Proper operation of VCSELs requires the preparation of highly-reflective DBR mirrors with precisely-controlled quarter-wavelength (¼ λ) layers with high- and low refractive indices, plus the need to control the position of the active gain region to be at an anti-node position within the vertical cavity. AlGaAs-based VCSELs, which represent a great success in infrared, include the use of in-situ reflectometer to monitor the evolution of reflectance with the use of DBRs having layers of sufficiently different optical refractive indices. However, using nanoporous DBRs presents a unique problem, in that index contrast is formed post-growth through conductivity-selective electrochemistry. During growth of the doped semiconductor layers with different conductivities on substrates made with the same semiconductor, there is very little difference in refractive indices among the layers and the substrate (Δn˜0.01). As such, the reflectometer used for the growth of VCSELs with DBRs formed post-growth no longer produces any reflectance oscillations that are needed to calibrate growth rates and layer thicknesses.

Accordingly, there is a need in the art for articles and methods that provide a solution to performing in-situ reflectance measurement in essentially a homoepitaxial process. The present invention addresses this need.

### SUMMARY

In one aspect, the present invention includes a semiconductor layered structure comprising a substrate layer including a semiconductor material; an index layer on the substrate layer; and at least one reflective layer on the index layer; wherein the substrate layer and the reflective layer include substantially the same refractive indices. In some embodiments, the semiconductor material comprises gallium nitride (GaN), gallium arsenide (GaAs), or indium phosphide (InP).

In some embodiments, the index layer comprises the semiconductor material doped with at least one other element. In some embodiments, the at least one other element comprises aluminum (Al), indium (In), or a combination thereof. In some embodiments, a concentration of the at least one other element in the index layer is at least about 1×10¹⁹ cm⁻³.

In some embodiments, the index layer comprises the semiconductor material alloyed with at least one other element. In some embodiments, the index layer comprises AlGaN, InGaN, AlInN, or AlGaInN. In some embodiments, the index layer is doped.

In some embodiments, a thickness of the index layer is between (⅙n)λ and (½n)λ of a reflectometer source, wherein n is a refractive index of the index layer.

In some embodiments, the substrate and the reflective layer are homoepitaxial.

In some embodiments, the reflective layer is nanoporous.

In some embodiments, the reflective layer comprises a vertical cavity surface emitting laser (VCSEL).

In some embodiments, a difference between refractive indices of the index layer and at least one of the substrate layer and the reflective layer is at least 0.01. In some embodiments, the difference between refractive indices is between 0.01 and 0.8.

In another aspect, the present invention includes a method of producing the semiconductor layered structure according to any one of the previous claims, the method comprising growing, via an epitaxial process, the reflective layer onto the index layer; measuring, via a reflectometer, a thickness of the reflective layer; and terminating the epitaxial process at a desired thickness of the reflective layer. In some embodiments, the reflective layer and the index layer include a refractive index difference of at least 0.01.

In some embodiments, the method further comprises, prior to the growing of the reflective layer, growing, via an epitaxial process, the index layer onto the substrate layer; measuring, via the reflectometer, a thickness of the index layer during the epitaxial process; and terminating the epitaxial process at a desired thickness of the index layer. In some embodiments, the index layer and the substrate layer include a refractive index difference of at least 0.01.

In some embodiments, the epitaxial process comprises metalorganic vapor phase epoxy.

In some embodiments, the semiconductor layered structure comprises a nanoporous distributed Bragg reflector (DBR).

### BRIEF DESCRIPTION OF THE DRAWINGS

For a fuller understanding of the nature and desired objects of the present invention, reference is made to the following detailed description taken in conjunction with the accompanying drawing figures wherein like reference characters denote corresponding parts throughout the several views.

FIG. 1 depicts schematic structures of light reflection at varying interfaces, according to an embodiment of the present disclosure.

FIG. 2 depicts simulated in-situ reflectance evolution for hetero- and homo-epitaxial gallium nitride (GaN) growth according to an embodiment of the present disclosure.

FIG. 3 depicts simulated in-situ reflectance evolution for homo-epitaxial GaN with various n⁺GaN layer, according to an embodiment of the present disclosure. λ is 550 nm. n⁺GaN thickness varies between λ/2n and λ/6n.

FIGS. 4A-B depict simulated in-situ reflectance evolution for multiple low and high index layers, according to an embodiment of the present disclosure. The curves indicate high index and low index layers, respectively. λ is 550 nm. (A) Multiple index layers with λ/4n-thick low-index and high index layers. (B) Multiple index layers with thin low-index layer (<λ/4n in thickness) and thick high-index layer (>λ/4n in thickness).

FIGS. 5A-B depicts reflectance evolution measured during n⁺ and n-GaN growth on n⁻ GaN template, according to an embodiment of the present disclosure. Due to lower refractive index of n⁺GaN than that of n-GaN, the reflectance decreases with n⁺GaN growth. (A) Growth time from 2600 s to 3000 s. (B) Growth time from 2000 s to 4500 s.

FIGS. 6A-B depict reflectance curves measured during u-AlGaN and n-GaN growth on n-GaN template, according to an embodiment of the present disclosure. Due to lower refractive index of u-AlGaN than that of n-GaN, reflectance decreases when u-AlGaN growth started. (A) Growth time from 2400 s to 3200 s. (B) Growth time from 2000 s to 4500 s.

FIGS. 7A-B depict reflectance curves measured during multiple n⁺ and n⁻GaN index layers targeting for (A) 550 nm and (B) 900 nm wavelengths, according to an embodiment of the present disclosure.

FIGS. 8A-B depict schematic epi structures of NP GaN-based VCSELs according to an embodiment of the present disclosure. (A) As-grown VCSEL epi structure. (B) Porosified VCSEL epi structure.

FIGS. 9A-C depict a schematic of GaN layer porosification. (A) Schematic epi structures of NP GaN VCSELs, according to an embodiment of the present disclosure. (B) Porosified n⁺GaN layers for NP GaN distributed Bragg reflectors (DBR) formation. (C) Porosified index layers, which contribute to reflection.

FIGS. 10A-C depict the structure and simulated reflectance of NP GaN DBR. (A) Schematic structure of NP GaN DBR with the porosified index layers. (B) Simulated reflectance at wavelengths of between 350 and 1100 nm. (C) Simulated reflectance at wavelengths of between 400 and 460 nm.

FIGS. 11A-B depict reflectance spectra of GaN DBR. (A) Simulated and experimentally measured reflectance spectra of NP GaN DBR with porosification of the index layers. (B) Reflectance spectra of typical NP GaN DBR without porosification of the index layers.

### DEFINITIONS

The instant invention is most clearly understood with reference to the following definitions.

As used herein, the singular form “a,” “an,” and “the” include plural references unless the context clearly dictates otherwise.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein are modified by the term about.

As used in the specification and claims, the terms “comprises,” “comprising,” “containing,” “having,” and the like can have the meaning ascribed to them in U.S. patent law and can mean “includes,” “including,” and the like.

Unless specifically stated or obvious from context, the term “or,” as used herein, is understood to be inclusive.

Ranges provided herein are understood to be shorthand for all of the values within the range. For example, a range of 1 to 50 is understood to include any number, combination of numbers, or sub-range from the group consisting 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 (as well as fractions thereof unless the context clearly dictates otherwise).

### DETAILED DESCRIPTION OF THE INVENTION

Provided herein are structures and methods for in-situ reflectance measurement during homo-epitaxy. In some embodiments, the structure includes a substrate, a reflective layer, and an index layer between the substrate and the reflective layer. In some embodiments, the reflective layer includes a distributed Bragg reflector (DBR). In some embodiments, the substrate and the reflective layer have the same or substantially the same refractive index (n). For example, in some embodiments, the substrate and the reflective layer are the same (homoepitaxial) or substantially the same material. Suitable materials for the substrate and/or reflective layer include, but are not limited to, semiconductors (e.g., gallium nitride (GaN), gallium arsenide (GaAs), or indium phosphide (InP)), or any other suitable material for forming a DBR and/or vertical cavity surface emitting laser (VCSEL).

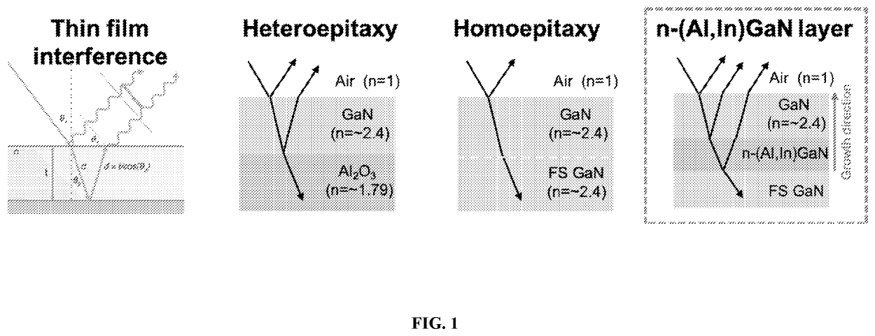

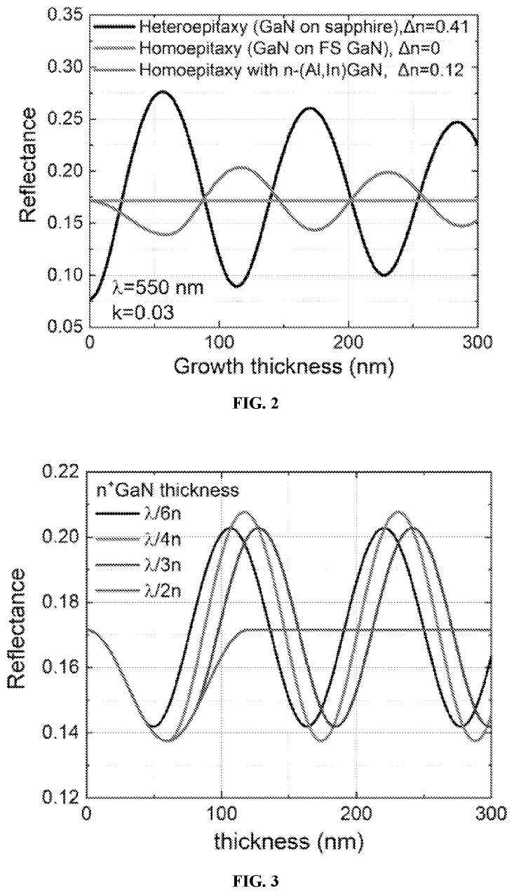

FIG. 1 (1^{st} panel) illustrates the basic principle of reflectance oscillations, which are due to constructive and destructive thin-film interferences between the reflections at the air/film and film/substrate interfaces as the thickness of the thin film increases during growth. The higher the difference in refractive index (Δn), the greater the induced reflectance oscillations for the subsequent growth. For example, during heteroepitaxy, such as in the case of GaN on sapphire (FIG. 1, 2^{nd} panel), reflectance oscillations from the interface between the substrate and the reflective layer can be seen. In contrast, during homoepitaxy, such as when the Al₂O₃ substrate is replaced with GaN (FIG. 1, 3^{rd} panel), there is no longer appreciable reflection from any buried interfaces, and therefore no observable oscillations. This is further illustrated in the simulations of heteroepitaxy and homoepitaxy of FIG. 2, where when the refractive indexes are the same or substantially the same (e.g., under homoepitaxy) there are no reflectance oscillations (flat curve) upon which to base in-situ monitoring of growth rates.

However, the incorporation of the index layer between the substrate and the reflective layer including the same or substantially the same refractive index, according to the embodiments disclosed herein, provides a change in refractive index therebetween to induce oscillations during growth of the layers. In some embodiments, the difference in refractive index between the index layer and the substrate and/or reflective layer includes, but is not limited to, at least 0.01, at least 0.02, at least 0.03, at least 0.04, at least 0.05, between 0.01 and 0.8, or any combination, sub-combination, range, or sub-range thereof. In some embodiments, the amplitude of the oscillations induced by the index layer is related to the material of the index layer. Accordingly, in some embodiments, the index layer includes any suitable material for introducing a change in refractive index as compared to the substrate and/or reflective layer. In some embodiments, the index layer includes a doped or undoped material that is different from the substrate and/or reflective layer. In some embodiments, the material includes a semiconductor alloyed with at least another element (e.g., AlGaN, InGaN, AlInN, AlGaInN). Additionally or alternatively, in some embodiments, the index layer includes a doped layer of the same material as the substrate and/or reflective layer (e.g., (Al,In)GaN, (Al,In)GaAs, or (Al,In)InP). For example, the use of an (Al,In)GaN index layer (FIG. 1, 4^{th} panel), with an index contrast of 0.12, provides reflectance signals that can oscillate with sufficient amplitude (FIG. 2) during the subsequent epitaxy, such that growth rate can be measured accurately in-situ even during the essentially homoepitaxy condition. Furthermore, in some embodiments, the index layers can be electrochemically etched to form an additional nanoporous mirror, enhancing reflectance.

As will be appreciated by those skilled in the art, different materials and different doping concentrations provide different levels of Δn. For example, in some embodiments, increasing the doping concentration of an n⁺-index layer (e.g., n⁺-GaN) increases Δn, resulting in enhanced oscillations. In some embodiments, the concentration of dopant in the index layer is at least about 1×10¹⁹ cm⁻³, between about 1×10¹⁹ cm⁻³ and 3×10²⁰ cm⁻³, or any suitable combination, sub-combination, range, or sub-range thereof. For example, the doping concentrations of the n⁺- and n⁻-index layers may include >3E19 and <1.5E19 cm⁻³, respectively. Alternatively, in some embodiments, the n⁺-X index layer is replaced with doped or undoped AlX index layers having low Al composition (e.g., between 3 and 20%), where X is any suitable substrate, reflective layer, or index layer material. In such embodiments, increasing the Al composition and/or doping concentration increases Δn. In some embodiments, as compared to a reflective layer of a different material, a reflective layer including a doped layer of the same material as the substrate and/or reflective layer provides a lower Δn and/or reduces complications in epitaxy (e.g., building up of strains, deterioration of morphology, or change of growth parameters (pressure, temperature, growth rates)).

In some embodiments, the thickness of the index layer may also be selected/adjusted to provide a desired/different amplitude of oscillation. In some embodiments, the thickness may be selected/adjusted to provide induced oscillations when Δn is limited. In some embodiments, the thickness of the index layer is between λ/8n and λ/2n, λ/8n and λ/3n, λ/7n and λ/2n, λ/7n and λ/3n, λ/6n and λ/2n, λ/6n (39 nm) and λ/3n (79 nm), λ/4n (59 nm), or any combination, sub-combination, range, or sub-range thereof. In some embodiments, the thickness of the index layer is between λ/6n (39 nm) and λ/3n (79 nm). In some embodiments, In some embodiments, the thickness of the index layer is λ/4n (59 nm). In some embodiments, for a given Δn, (m/2−¼)λ/n thickness, where m is an integer, provides maximum oscillation amplitude, whereas mλ/2n thickness results in minimum oscillation amplitude. In some embodiments, a thickness of (m/2± 1/12)λ/n decreases the oscillation amplitude by 50%.

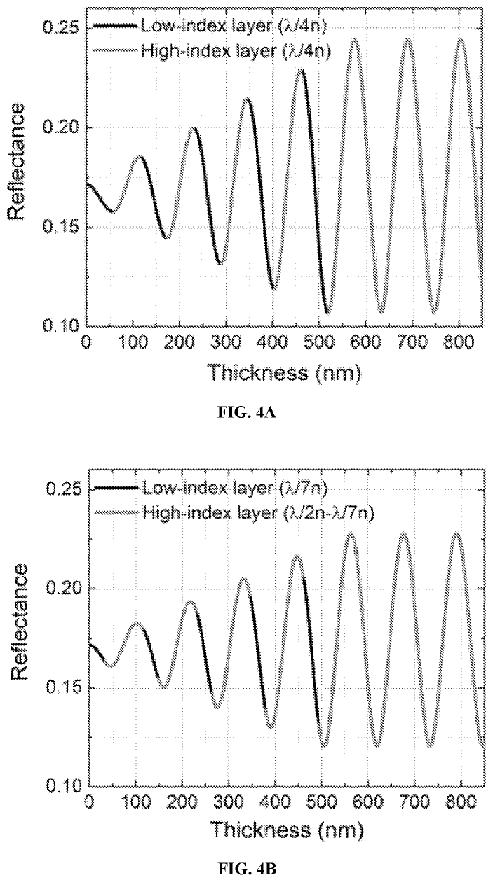

In some embodiments, the thickness may be selected to provide a suitable amplitude of reflectance oscillations with a limited index contrast. For example, even when a heavily-doped GaN index layer (n˜2.38 at 633 nm) provides limited contrast (Δn˜0.1) with undoped GaN (n˜2.44 at 633 nm), a thickness of the index layer can be chosen to provide a sufficient amplitude of the induced oscillations. Referring to FIG. 3, which shows a simulation indicating reflectance oscillations using index layers of different thicknesses, an index layer with a thickness of λ/4n would give the maximum oscillation amplitude. A thickness of λ/6n or λ/3n also produces good amplitude, while a thickness of λ/2n leads to minimal oscillation. The corresponding variation of oscillation amplitude as a function of the thickness of the index layer is shown in FIG. 4A, assuming the reflectance is measured at λ=550 nm.

Additionally or alternatively, in some embodiments, multiple layers of reflective material can be used to increase the oscillation amplitude. Suitable layers include, but are not limited to, n⁺-GaN/u-GaN, n⁺-GaN/n⁻GaN, n⁺-AlGaN/u-GaN, n⁺-AlGaN/n⁻GaN, or u-AlGaN/u-GaN. For example, as illustrated in FIG. 4A, multiple index layers with λ/4n-thick low-index and high index layers can boost the oscillation amplitude. The low-index layer can be n⁺-GaN, n⁺-AlGaN, or u-AlGaN. To minimize the strain building up and/or surface deterioration, the multiple index layers can be composed of thin low-index layer (<λ/4n in thickness) and thick high-index layer (>/4n in thickness) while keeping the pair thickness of ˜λ/2n (FIG. 4B). Even though thin low-index layer reduces the oscillation amplitude, it can ease complications in epitaxy.

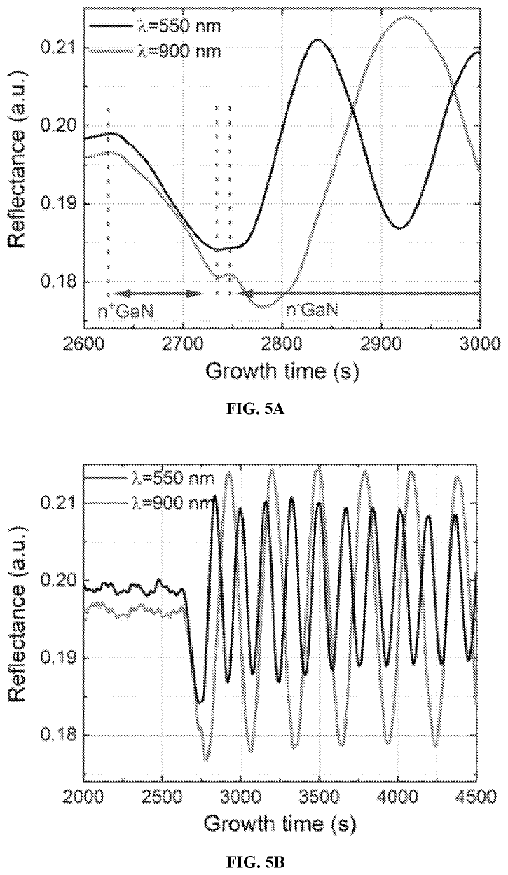

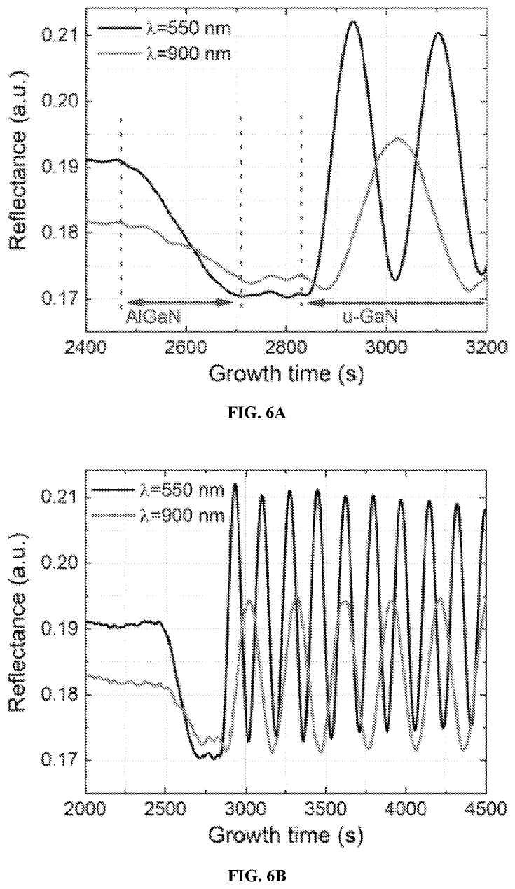

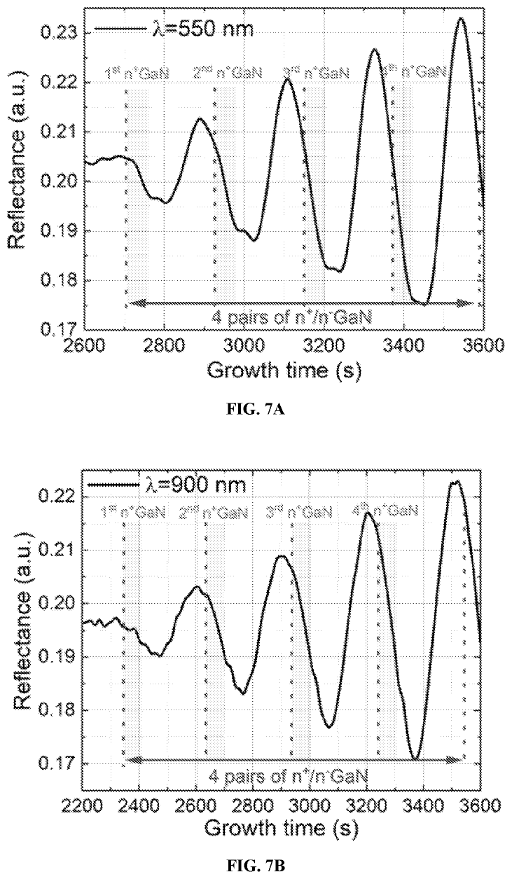

The structure according to the embodiments disclosed herein provide induced and sustained oscillations during GaN homoepitaxy, with various index layers and reflectance wavelengths (λ=550 nm and 900 nm). For example, FIGS. 5A-B and 6A-B depict the reflectance with n⁺GaN, and u-AlGaN index layers, respectively. Due to lower refractive indices of n⁺GaN and AlGaN, as compared to u-GaN (or n⁻GaN), the reflectance decreased almost as soon as n⁺GaN (or AlGaN) growth started. The sustained oscillations at both wavelengths are shown in FIGS. 5A-B and 6A-B. Additionally, multiple index layers may be included, as illustrated in FIGS. 7A-B, which depict in-situ reflectance spectra of multiple n⁺GaN index layers. Since the pair thickness is close to λ/2n, the reflectance amplitude increases with increasing the n⁺/n⁻GaN pairs.

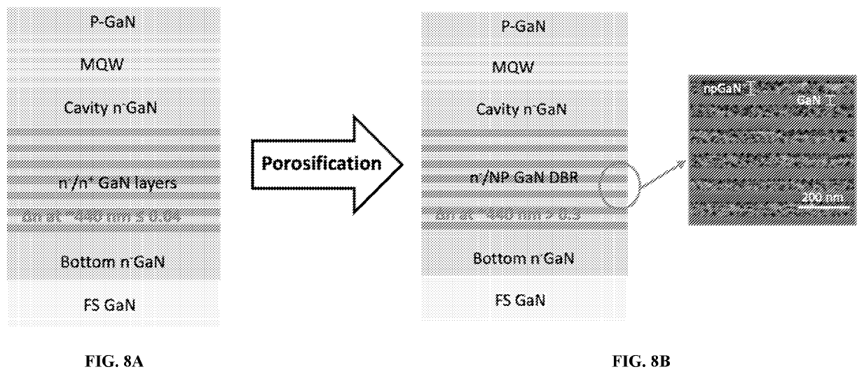

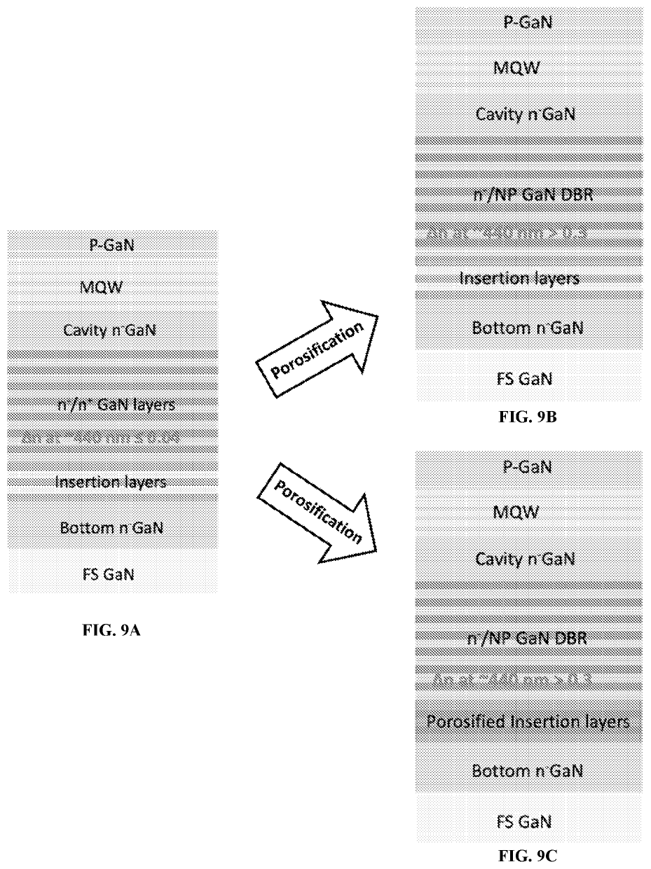

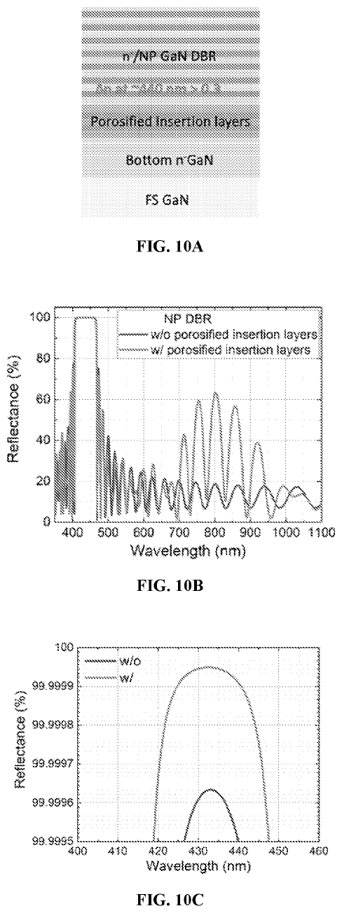

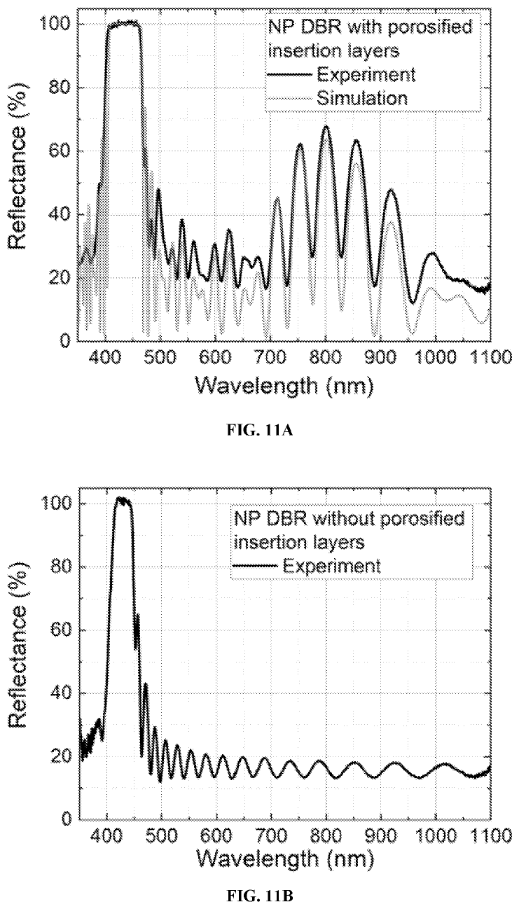

Also provided herein is a VCSEL formed using the structure according to one or more of the embodiments disclosed herein. In some embodiments, the reflective layer includes a VCSEL. FIGS. 8A-B depict the schematic epi structures of NP GaN VCSEL. As illustrated therein, after porosification, n⁻GaN turns to NP GaN, resulting in DBR formation (FIG. 8B). For in-situ monitoring and controlling thicknesses of cavity and n⁻/n⁺GaN layers, the index layers can be placed underneath the n⁻/n⁺GaN layers (FIGS. 9A-B). If the index contains n⁺GaN or n⁺AlGaN, they can be porosified and act as additional n⁻side mirror (FIG. 9C). According to a simulation, the porosified index layer (FIG. 10A) can generate a broad peak at about 800 nm (FIG. 10B), and their 2^{nd} harmonic oscillation peak can enhance the reflectance at about 430 nm (FIG. 10C). FIGS. 11A-B depict measured reflectance of NP DBR with and without porosification of the index layers.

Further provided herein is a method of producing a nanoporous (NP) distributed Bragg reflector (DBR). In some embodiments, the method includes growing, via an epitaxial process, the reflective layer onto the index layer; measuring, via a reflectometer, a thickness of the reflective layer; and maintaining the thickness of the reflective layer by terminating the other epitaxial process. In some embodiments, prior to growing the reflective layer, the method includes growing, via an epitaxial process, the index layer onto the substrate layer; measuring, via a reflectometer, a thickness of the index layer during the epitaxial process; and maintaining the thickness of the index layer by terminating the epitaxial process. In some embodiments, the epitaxial process includes metalorganic vapor phase epoxy.

The embodiments disclosed herein enable in-situ thickness monitoring and control in an essentially homoepitaxial structure, including, but not limited to, the thickness of semiconductor layers during the manufacturing of VCSELs with distributed Bragg reflectors made from the same material as the substrate (e.g., GaN DBRs on GaN substrates, InP DBRs on InP substrates). The ability to measure and control the thickness of homoepitaxial layers in-situ further enables the reliable and reproducible production of VCSELs. Additionally, the use of an extra index underlayer greatly enhances the manufacturability of VCSELs from porous layers.

### EQUIVALENTS

Although preferred embodiments of the invention have been described using specific terms, such description is for illustrative purposes only, and it is to be understood that changes and variations may be made without departing from the spirit or scope of the following claims.

### Enumerated Embodiments

In some embodiments, the instant specification is directed to the following non-limiting embodiments:
Embodiment 1: A semiconductor layered structure comprising a substrate layer including a semiconductor material; an index layer on the substrate layer, the index layer including a doped version of the semiconductor material; and at least one reflective layer on the index layer; wherein the substrate layer and the reflective layer include substantially the same refractive indices.
Embodiment 2: The semiconductor layered structure of embodiment 1, wherein the semiconductor material comprises gallium nitride (GaN), gallium arsenide (GaAs), or indium phosphide (InP).
Embodiment 3: The semiconductor layered structure of any of the previous embodiments, wherein a thickness of the index layer is dependent on a wavelength of a reflectometer source.
Embodiment 4: The semiconductor layered structure of any of the previous embodiments, wherein a thickness of the index layer is between (⅙n)λ and (½n)λ of a reflectometer source, wherein n is a refractive index of the index layer.
Embodiment 5: The semiconductor layered structure of any of the previous embodiments, wherein the index layer is doped with at least one other element comprising Al, In, or a combination thereof.
Embodiment 6: The semiconductor layered structure of any of the previous embodiments, wherein a concentration of an n⁻dopant in the index layer is about 1×10¹⁹ cm⁻³ or higher, or ranges from about 1×10¹⁹ cm⁻³ to 3×10²⁰ cm⁻³.
Embodiment 7: The semiconductor layered structure of any of the previous embodiments, wherein the substrate and the reflective layer are homoepitaxial.
Embodiment 8: The semiconductor layered structure of any of the previous embodiments, wherein the reflective layer is nanoporous.
Embodiment 9: The semiconductor layered structure of any of the previous embodiments, wherein the nanoporous layer comprises a vertical cavity surface emitting laser (VCSEL).
Embodiment 10: The semiconductor layered structure of any of the previous embodiments, wherein a difference between refractive indices of the index layer and at least one of the substrate layer and the reflective layer is at least 0.01.
Embodiment 11: The semiconductor layered structure of any of the previous embodiments, wherein a difference between refractive indices of the index layer and at least one of the substrate layer and the reflective layer is between 0.01 and 0.8.
Embodiment 12: A semiconductor layered structure comprising a substrate layer including a semiconductor material; an index layer on the substrate layer, the index layer comprising the semiconductor material alloyed with at least another element; and at least one reflective layer on the index layer; wherein the substrate layer and the reflective layer include substantially the same refractive indices.
Embodiment 13: The semiconductor layered structure of embodiment 12, wherein the semiconductor material comprises gallium nitride (GaN), gallium arsenide (GaAs), or indium phosphide (InP).
Embodiment 14: The semiconductor layered structure of embodiment 12 or 13, wherein the semiconductor material comprises GaN, and the index layer comprises additional element such as Indium or Aluminum.
Embodiment 15: The semiconductor layered structure of any of embodiments 12-14, wherein a thickness of the index layer is dependent on a wavelength of a reflectometer source.
Embodiment 16: The semiconductor layered structure of any of embodiments 12-15, wherein a thickness of the index layer is between (⅙n)λ and (½n)λ of a reflectometer source, wherein n is a refractive index of the index layer.
Embodiment 17: The semiconductor layered structure of any of embodiments 12-16, wherein the substrate and the reflective layer are homoepitaxial.
Embodiment 18: The semiconductor layered structure of any of embodiments 12-17, wherein the reflective layer is nanoporous.
Embodiment 19: The semiconductor layered structure of any of embodiments 12-18, wherein the nanoporous layer comprises a vertical cavity surface emitting laser (VCSEL).
Embodiment 20: The semiconductor layered structure of any of embodiments 12-19, wherein a difference between refractive indices of the index layer and at least one of the substrate layer and the reflective layer is at least 0.01.
Embodiment 21: The semiconductor layered structure of any of embodiments 12-20, wherein a difference between refractive indices of the index layer and at least one of the substrate layer and the reflective layer is between 0.01 and 0.8.
Embodiment 22: A method of producing the semiconductor layered structure according to any one of the previous embodiments, the method comprising growing, via an epitaxial process, the reflective layer onto the index layer; measuring, via a reflectometer, a thickness of the reflective layer; and terminating the epitaxial process at a desired thickness of the reflective layer.
Embodiment 23: The method of embodiment 22, wherein the reflective layer and the index layer include a refractive index difference of at least 0.01.
Embodiment 24: The method of embodiment 22 or 23, further comprising, prior to the growing of the reflective layer growing, via an epitaxial process, the index layer onto the substrate layer; measuring, via the reflectometer, a thickness of the index layer during the epitaxial process; and terminating the epitaxial process at a desired thickness of the index layer.
Embodiment 25: The method of any of embodiments 22-24, wherein the index layer and the substrate layer include a refractive index difference of at least 0.01.
Embodiment 26: The method of any of embodiments 22-25, wherein the epitaxial process comprises metalorganic vapor phase epoxy.
Embodiment 27: The method of any embodiments 22-26, wherein the semiconductor layered structure comprises a nanoporous distributed Bragg reflector (DBR).

### INCORPORATION BY REFERENCE

The entire contents of all patents, published patent applications, and other references cited herein are hereby expressly incorporated herein in their entireties by reference.

1. A semiconductor layered structure comprising:
a substrate layer including a semiconductor material;
an index layer on the substrate layer; and
at least one reflective layer on the index layer;
wherein the substrate layer and the reflective layer include substantially the same refractive indices.

2. The semiconductor layered structure of claim 1, wherein the semiconductor material comprises gallium nitride (GaN), gallium arsenide (GaAs), or indium phosphide (InP).

3. The semiconductor layered structure of claim 1, wherein the index layer comprises the semiconductor material doped with at least one other element.

4. The semiconductor layered structure of claim 3, wherein the at least one other element comprises Al, In, or a combination thereof.

5. The semiconductor layered structure of claim 1, wherein a concentration of the at least one other element in the index layer is at least about 1×10¹⁹ cm⁻³.

6. The semiconductor layered structure of claim 1, wherein the index layer comprises the semiconductor material alloyed with at least one other element.

7. The semiconductor layered structure of claim 6, wherein the index layer comprises AlGaN, InGaN, AlInN, or AlGaInN.

8. The semiconductor layered structure of claim 6, wherein the index layer is doped.

9. The semiconductor layered structure of claim 1, wherein a thickness of the index layer is between (⅙n)λ and (½n)λ of a reflectometer source, wherein n is a refractive index of the index layer.

10. The semiconductor layered structure of claim 1, wherein the substrate and the reflective layer are homoepitaxial.

11. The semiconductor layered structure of claim 1, wherein the reflective layer is nanoporous.

12. The semiconductor layered structure of any one of the previous claims, wherein the reflective layer comprises a vertical cavity surface emitting laser (VCSEL).

13. The semiconductor layered structure of claim 1, wherein a difference between refractive indices of the index layer and at least one of the substrate layer and the reflective layer is at least 0.01.

14. The semiconductor layered structure of claim 13, wherein the difference between refractive indices is between 0.01 and 0.8.

15. A method of producing the semiconductor layered structure according to any one of the previous claims, the method comprising:
growing, via an epitaxial process, the reflective layer onto the index layer;
measuring, via a reflectometer, a thickness of the reflective layer; and
terminating the epitaxial process at a desired thickness of the reflective layer.

16. The method of claim 15, wherein the reflective layer and the index layer include a refractive index difference of at least 0.01.

17. The method of claim 15, further comprising, prior to the growing of the reflective layer:
growing, via an epitaxial process, the index layer onto the substrate layer;
measuring, via the reflectometer, a thickness of the index layer during the epitaxial process; and
terminating the epitaxial process at a desired thickness of the index layer.

18. The method of claim 17, wherein the index layer and the substrate layer include a refractive index difference of at least 0.01.

19. The method of claim 15, wherein the epitaxial process comprises metalorganic vapor phase epoxy.

20. The method of claim 15, wherein the semiconductor layered structure comprises a nanoporous distributed Bragg reflector (DBR).
